(19) United States
(12) Patent Application Publication
(10) Pub. No.: US 2021/0129178 A1
(43) Pub. Date: May 6, 2021

(54) COMBINATION PARYLENE SYSTEM FOR PRE-TREATMENT, DEPOSITION, POST-TREATMENT AND CLEANING

(71) Applicant: HZO, Inc., Morrisville, NC (US)

(72) Inventors: John Janik, Raleigh, NC (US); Benjamin Lawrence, Salt Lake City, UT (US)

(21) Appl. No.: 16/669,423

(22) Filed: Oct. 30, 2019

(51) Int. Cl. B05D 1/00; H01J 37/32; B05D 3/06; B05D 3/14

(52) U.S. Cl. CPC B05D 1/60; H01J 37/32862; B05D 3/06; H01J 37/32082; H01J 2237/332; H01J 2237/334; H01J 37/32192; B05D 3/142

(57) ABSTRACT

A deposition system includes a multipurpose deposition chamber, a pre-treatment source and a post-treatment source. The multipurpose deposition chamber is configured to deposit parylene on a plurality of electronic devices. The multipurpose deposition chamber is configured to process pre-treatment of the plurality of electronic devices prior to deposition of the parylene. The multipurpose deposition chamber is configured to process post-treatment of the plurality of electronic devices after deposition of the parylene.

### BACKGROUND

This disclosure relates generally to deposition of protective coatings on substrates of electronic devices. More specifically, this disclosure relates to a combination of two or more of pre-treatment processes, deposition processes, post-treatment processes, and/or cleaning of substrates of electronic devices in a chamber. In addition, this disclosure relates to in situ O₂, C₄F₈, SF₆, and other fluorinated gas treatments for increased hydrophobicity. Additionally, this disclosure relates to plasma etching for chamber cleaning.

### SUMMARY

The subject matter of the present application has been developed in response to the present state of the art, and in particular, in response to the problems and disadvantages associated with conventional parylene systems that have not yet been fully solved by currently available techniques. Accordingly, the subject matter of the present application has been developed to provide embodiments of a combination parylene system and in situ treatment that overcome at least some of the shortcomings of prior art techniques.

Disclosed herein is a method for depositing parylene onto a substrate. The method includes depositing a parylene on a substrate in a multipurpose deposition chamber. The method further includes performing at least one pre-treatment process on the substrate before depositing the parylene in the multipurpose deposition chamber or performing at least one post-treatment process on the substrate after depositing the parylene in the multipurpose deposition chamber. The method further includes maintaining pressure in the multipurpose deposition chamber between the depositing the parylene and the performing the at least one pre-treatment process or the performing the at least one post-treatment process. The preceding subject matter of this paragraph characterizes example 1 of the present disclosure.

The method includes performing the at least one pre-treatment process on the substrate before depositing the parylene in the multipurpose deposition chamber and performing the at least one post-treatment process on the substrate after depositing the parylene in the multipurpose deposition chamber. The preceding subject matter of this paragraph characterizes example 2 of the present disclosure, wherein example 2 also includes the subject matter according to example 1, above.

The at least one pre-treatment process is a radio-frequency, direct current, microwave, or hot filament plasma pre-treatment of the substrate. The preceding subject matter of this paragraph characterizes example 3 of the present disclosure, wherein example 3 also includes the subject matter according to any one of examples 1-2, above.

The at least one pre-treatment process is an O₂, or an O₂/Ar plasma pre-treatment of the substrate. The preceding subject matter of this paragraph characterizes example 4 of the present disclosure, wherein example 4 also includes the subject matter according to any one of examples 1-3, above.

The at least one post-treatment process is an O₂/SF₆ plasma post-treatment of the substrate. The preceding subject matter of this paragraph characterizes example 5 of the present disclosure, wherein example 5 also includes the subject matter according to any one of examples 1-4, above.

The method includes performing a cleaning of the multipurpose deposition chamber, wherein the cleaning is done by etching. The preceding subject matter of this paragraph characterizes example 6 of the present disclosure, wherein example 6 also includes the subject matter according to any one of examples 1-5, above.

The method includes maintaining pressure in the multipurpose deposition chamber between the performing the at least one pre-treatment process and the depositing the parylene and maintaining pressure in the multipurpose deposition chamber between the depositing the parylene and the performing the at least one post-treatment process. The preceding subject matter of this paragraph characterizes example 7 of the present disclosure, wherein example 7 also includes the subject matter according to any one of examples 1-6, above.

The method includes applying a plasma etching to the multipurpose deposition chamber after performing the post-treatment. The preceding subject matter of this paragraph characterizes example 8 of the present disclosure, wherein example 8 also includes the subject matter according to any one of examples 1-7, above.

The post-treatment process includes an oxygen treatment. The preceding subject matter of this paragraph characterizes example 9 of the present disclosure, wherein example 9 also includes the subject matter according to any one of examples 1-8, above.

The post-treatment process includes a fluorinated gas treatment. The preceding subject matter of this paragraph characterizes example 10 of the present disclosure, wherein example 10 also includes the subject matter according to any one of examples 1-9, above.

Disclosed herein is a deposition system. The system includes a multipurpose deposition chamber configured to deposit parylene on a plurality of electronic devices, wherein the multipurpose deposition chamber is configured to also process pre-treatment of the plurality of electronic devices prior to deposition of the parylene or process post-treatment of the plurality of electronic devices after deposition of the parylene. The preceding subject matter of this paragraph characterizes example 11 of the present disclosure.

The system includes a capacitively coupled radio frequency plasma generation system coupled to the multipurpose deposition chamber. The preceding subject matter of this paragraph characterizes example 12 of the present disclosure, wherein example 12 also includes the subject matter according to example 11, above.

The system includes a remote radio frequency plasma generation system coupled to the multipurpose deposition chamber. The preceding subject matter of this paragraph characterizes example 13 of the present disclosure, wherein example 13 also includes the subject matter according to any one of examples 11-12, above.

The system includes a microwave plasma generation system. The preceding subject matter of this paragraph characterizes example 14 of the present disclosure, wherein example 14 also includes the subject matter according to any one of examples 11-13, above.

The at least one post-treatment process is a halogenated gas post-treatment of the substrate. The preceding subject matter of this paragraph characterizes example 15 of the present disclosure, wherein example 15 also includes the subject matter according to any one of examples 11-14, above.

The system includes a pre-treatment source coupled to the multipurpose deposition chamber. The preceding subject matter of this paragraph characterizes example 16 of the present disclosure, wherein example 16 also includes the subject matter according to any one of examples 11-15, above.

The system includes a post-treatment source coupled to the multipurpose deposition chamber. The preceding subject matter of this paragraph characterizes example 17 of the present disclosure, wherein example 17 also includes the subject matter according to any one of examples 11-16, above.

The at least one pre-treatment process is an O₂/Ar plasma pre-treatment of the substrate. The preceding subject matter of this paragraph characterizes example 18 of the present disclosure, wherein example 18 also includes the subject matter according to any one of examples 11-17, above.

Disclosed herein is a deposition system. The system includes a multipurpose deposition chamber configured to deposit parylene on a plurality of electronic devices. The multipurpose deposition chamber is configured to process pre-treatment of the plurality of electronic devices prior to deposition of the parylene. The multipurpose deposition chamber is configured to process post-treatment of the plurality of electronic devices after deposition of the parylene. The system includes a pre-treatment source coupled to the multipurpose deposition chamber and a post-treatment source coupled to the multipurpose deposition chamber. The preceding subject matter of this paragraph characterizes example 19 of the present disclosure.

The system includes a capacitively coupled radio frequency plasma generation system coupled to the multipurpose deposition chamber. The preceding subject matter of this paragraph characterizes example 20 of the present disclosure, wherein example 20 also includes the subject matter according to example 19, above.

The described features, structures, advantages, and/or characteristics of the subject matter of the present disclosure may be combined in any suitable manner in one or more embodiments and/or implementations. In the following description, numerous specific details are provided to impart a thorough understanding of embodiments of the subject matter of the present disclosure. One skilled in the relevant art will recognize that the subject matter of the present disclosure may be practiced without one or more of the specific features, details, components, materials, and/or methods of a particular embodiment or implementation. In other instances, additional features and advantages may be recognized in certain embodiments and/or implementations that may not be present in all embodiments or implementations. Further, in some instances, well-known structures, materials, or operations are not shown or described in detail to avoid obscuring aspects of the subject matter of the present disclosure. The features and advantages of the subject matter of the present disclosure will become more fully apparent from the following description and appended claims, or may be learned by the practice of the subject matter as set forth hereinafter.

### BRIEF DESCRIPTION OF THE DRAWINGS

In order that the advantages of the subject matter may be more readily understood, a more particular description of the subject matter briefly described above will be rendered by reference to specific embodiments that are illustrated in the appended drawings. Understanding that these drawings depict only typical embodiments of the subject matter and are not therefore to be considered to be limiting of its scope, the subject matter will be described and explained with additional specificity and detail through the use of the drawings, in which:

FIG. 1 is a multipurpose deposition chamber, according to one or more embodiments of the present disclosure;

FIG. 2 is a multipurpose deposition chamber, according to one or more embodiments of the present disclosure;

FIG. 3 is a schematic block diagram of a method, according to one or more embodiments of the present disclosure;

FIG. 4 is a multipurpose deposition chamber, according to one or more embodiments of the present disclosure;

FIG. 5 is a multipurpose deposition chamber, according to one or more embodiments of the present disclosure; and

FIG. 6 is a schematic block diagram of a method, according to one or more embodiments of the present disclosure.

### DETAILED DESCRIPTION

Reference throughout this specification to “one embodiment,” “an embodiment,” or similar language means that a particular feature, structure, or characteristic described in connection with the embodiment is included in at least one embodiment of the present disclosure. Appearances of the phrases “in one embodiment,” “in an embodiment,” and similar language throughout this specification may, but do not necessarily, all refer to the same embodiment. Similarly, the use of the term “implementation” means an implementation having a particular feature, structure, or characteristic described in connection with one or more embodiments of the present disclosure, however, absent an express correlation to indicate otherwise, an implementation may be associated with one or more embodiments.

It will be readily understood that the components of the embodiments as generally described herein and illustrated in the appended figures could be arranged and designed in a wide variety of different configurations. Thus, the following more detailed description of various embodiments, as represented in the figures, is not intended to limit the scope of the present disclosure, but is merely representative of various embodiments. While the various aspects of the embodiments are presented in drawings, the drawings are not necessarily drawn to scale unless specifically indicated.

Other aspects, as well as features and advantages of various aspects, of the disclosed subject matter will be apparent to those of ordinary skill in the art through consideration of this disclosure and the appended claims.

Moisture resistant coatings or films, as well as other coatings or films are used to protect various parts of electronic devices (or substrates) from external influences. Protective coatings, such as parylene, are deposited on parts of the electronic devices in deposition chambers. Parylene, and other protective coatings, are deposited on the parts of electronic devices in various methods and processes. Some of those processes, examples of which are described by U.S. Patent Application Publication Nos. 2009/0263581, 2009/0263641, 2009/0304549, 2010/0203347, 2010/0293812, and 2011/0262740, the entire disclosures of each of which are, by this reference, incorporated herein. The disclosures describe embodiments of equipment and/or processes that may be employed to apply a protective coating.

In many cases, the electronic devices are subjected to pre-treatment processes which may be configured to prepare the electronic devices to better receive the protective coating. In some cases, post-treatment processes are applied to electronic devices and the protective coating(s) to enhance properties of the protective coating or other reasons.

Typically, pre-treatment processes, deposition processes, and post-treatment processes occur in specialized chambers or locations and the processing of electronic devices occurs in batches. For example, the electronic devices may proceed, as a batch, from a pre-treatment station to a separate deposition station and, finally, to a separate post-treatment station. This allows a batch of electronic devices to be pre-treated at a pre-treatment station while a different batch of electronic devices is at the deposition station. The movement of the electronic devices along such an assembly line can lead to bottlenecks and potentially to degradation of properties. The effect of some processes may degrade in transport between the various stations because of a lack of specialized conditions (e.g., pressure (either pressurized or de-pressurized compartment), temperature, etc.).

Embodiments of the invention described herein include a parylene deposition system that combines pre-treatment processes with the deposition processes in a single chamber, such as a multipurpose chamber. Some embodiments of the invention described herein include a parylene deposition system that combines post-treatment processes with the deposition processes in a single multipurpose chamber. Some embodiments includes combine both pre-treatment processes and post-treatment processes with the deposition processes in a single multipurpose chamber.

Some embodiments also combine cleaning processes in the single multipurpose chamber as well. Some embodiments combine multiple parts of the process into one system, such as pre-treatment, deposition, post-treatment, and chamber cleaning.

Embodiments of the invention include a multipurpose deposition chamber configured to do pre-treatment processes and deposition processes in situ in the multipurpose deposition chamber. In some embodiments, the multipurpose deposition chamber is configured to do deposition processes and post-treatment processes in situ in the multipurpose deposition chamber. In some embodiments, the multipurpose deposition chamber is configured to do pre-treatment processes, deposition processes, and post-treatment processes in situ in the multipurpose deposition chamber.

Some embodiments reduce capital and operating costs in parylene deposition. Some embodiments combine a capacitively coupled plasma system and a deposition system in a combined system that incorporates pre-treatment processes, post-treatment processes and deposition processes in a single multipurpose chamber.

In some embodiments, at least one pre-treatment process is performed in a multipurpose deposition chamber prior to deposition of a protective coating. In some embodiments, the pre-treatment processes may be configured to prepare a substrate for application of a protective coating, such as parylene. A substrate may include any part of or entirety of an electrical device, an industrial device, a vehicular device, a precision mechanical device, a medical device, a scientific instrument or the like, or a subcomponent of the like.

In some embodiments, one of the pre-treatment processes is an adhesion promotion process. The adhesion promotion process is configured to enhance adhesion of the parylene (or other protective coating) to a substrate during a subsequent parylene deposition process.

The pre-treatment process may include at least one of a number of processes or a combination of one or more of those processes described herein which occur in situ in the multipurpose deposition chamber prior to deposition of the protective coating. In some embodiments, the multipurpose deposition chamber includes a plasma generation system. In some embodiments, the plasma generation system is a remote plasma generation system that is coupled to the multipurpose deposition chamber. In some embodiments, the plasma generation system generates plasma in situ within the multipurpose deposition chamber.

In some embodiments, the plasma generation system includes a multi-phase RF generation system. In some embodiments, the plasma generation system includes electrodes that spaced with the multipurpose deposition chamber to generate the plasma within the multipurpose deposition chamber. RF may, in some embodiments, be more energy efficient than a microwave plasma generation system. In addition, RF may also be less costly, more flexible and scalable, more reliable, and require less maintenance. In some embodiments, the plasma generation system includes a microwave plasma generation system.

In some embodiments, the pre-treatment process includes O₂/Ar plasma pre-treatment. The O₂/Ar plasma pre-treatment may enhance adhesion of the parylene (or other protective coating) during the parylene (or other protective coating) deposition process. In some embodiments, the O₂/Ar plasma may be generated in situ. In some embodiments, the O₂/Ar plasma may be generated remotely and input into the multipurpose deposition chamber.

In some embodiments, the pre-treatment process includes pre-treating the substrate with a gas. In some embodiments, the gas may be configured to create radical sites. In some embodiments, the gas may be configured for surface roughening. As an example, oxygen may be used to pre-treat the substrate to create radical sites on the substrate. The radical sites may promote adhesion of the parylene coating. By performing the pre-treatment steps in the same multipurpose deposition chamber the radical sites remain active and ready for the deposition process. Transporting the substrate to another deposition chamber may degrade or deactivate the radical sites. During transportation the radical sites may interact with air or dust or water vapor to deactivate the radical sites.

In some embodiments, the multipurpose deposition chamber remains under vacuum during the pre-treatment processes and the deposition processes. That is, the vacuum is not broken between the pre-treatment process(es) and the deposition process(es). By maintaining a vacuum in the multipurpose deposition chamber, the radical sites on the substrate may not inadvertently discharge prior to the deposition process(es). In addition, there is less chance that the radical sites will react with air or dust or water vapor.

In one embodiment, the multipurpose deposition chamber is configured as a de-gas chamber. A de-gas chamber may be configured to remove contaminants or volatile compounds from a substrate before a coating of protective material is applied to the substrate. After de-gassing occurs the deposition of the parylene may occur without the need to move the substrate to a separate deposition chamber.

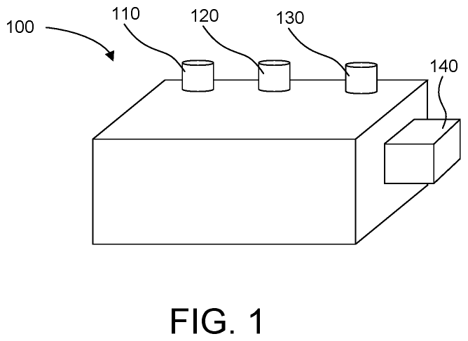

Referring to FIG. 1, a multipurpose deposition chamber 100 may include a plurality of inlets including a pre-treatment inlet valve 110, a deposition inlet valve 120, and a post-treatment inlet valve 130. In some embodiments, the pre-treatment inlet valve 110 and the post-treatment inlet valve 130 are combined in a single valve. In some embodiments, the pre-treatment inlet valve 110 and the post-treatment inlet valve 130 are configured close during the deposition of parylene to reduce or eliminate contamination by the parylene (or other protective coating).

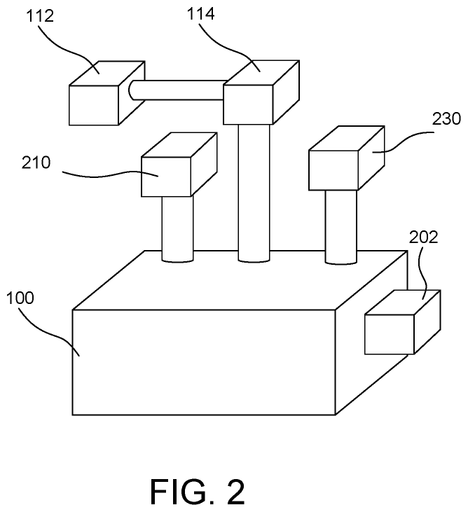

Referring to FIG. 2, a multipurpose deposition chamber 100 is coupled to a vaporizer 112 and a pyrolizer 114 which process the parylene prior to entering the multipurpose deposition chamber 100. In some embodiments, the system includes means for maintaining a pressure (e.g., a negative pressure, or vacuum, etc.) within the multipurpose deposition chamber 100. The multipurpose deposition chamber 100 may communicate with a vacuum pump and other elements that may facilitate the deposition of parylene material onto the substrate. One or more valves may also control the flow of the parylene materials through the system and onto the substrate. The illustrated embodiment includes a conduit between the pyrolizer 114 and the multipurpose deposition chamber 100. The illustrated embodiment also includes a conduit between the pyrolizer 114 and the vaporizer 112. In some embodiments, the conduit includes a valve to regulate the flow of material from the pyrolizer 114 to the multipurpose deposition chamber 100.

The vaporizer 112 may vaporize one or more types of parylene precursors for the formation of parylene materials such as parylene C (poly(chloro-p-xylylene)), parylene F (which can specifically refer to parylene-VT4, parylene-AF4, or any other parylene with a fluorine atom or atoms in the molecular structure), parylene N (poly(p-xylylene)), parylene D (poly(dichloro-p-xylylene)), parylene A (amino-modified parylene), etc.

In some embodiments, the multipurpose deposition chamber 100 may also be coupled to a pre-treatment source 210. The pre-treatment source 210 may be configured to produce, generate, or provide gases or other components or products used for the pre-treatment processes described herein. In some embodiments, the components or products may be provided directly into the multipurpose deposition chamber 100. In some embodiments, the components or products may be further processed within the multipurpose deposition chamber 100 by a plasma generation system 202. In some embodiments, the plasma generation system 202 is coupled to the multipurpose deposition chamber 100 as depicted in FIG. 2.

In some embodiments, the multipurpose deposition chamber 100 may also be coupled to a post-treatment source 230. The post-treatment source 230 may be configured to produce, generate, or provide gases or other components used for the post-treatment processes described herein. In some embodiments, the components or products may be provided directly into the multipurpose deposition chamber 100. In some embodiments, the components or products may be further processed within the multipurpose deposition chamber 100 by a plasma generation system 202. In some embodiments, the plasma generation system 202 is coupled to the multipurpose deposition chamber 100 as depicted in FIG. 2.

In some embodiments, the multipurpose deposition chamber 100 may be coupled to both the pre-treatment source 210 and the post-treatment source 230. In some embodiments, the multipurpose deposition chamber 100 may be coupled to only the pre-treatment source 210. In other embodiments, the multipurpose deposition chamber 100 may be coupled to only the post-treatment source 230.

In some embodiments, the multipurpose deposition chamber 100 is coupled to or includes a plasma generation system 202. The plasma generation system 202, in FIG. 2, is an in situ plasma generation system. In other embodiments, the plasma generation system 202 remotely generates plasma which is then provided to the multipurpose deposition chamber 100. In some embodiments, the plasma may be generated by radio frequency. In other embodiments, the plasma may be generated by microwaves. Other forms of energy are contemplated to generate the plasma.

After applying the pre-treatment processes to the substrate, deposition of a protective coating, such as parylene, is performed in the multipurpose deposition chamber 100. The protective coatings applied to surfaces of the substrate may impart moisture resistance to the substrate. As used herein, the terms “moisture-resistant” and “moisture-resistance” refer to the ability of a coating to prevent exposure of a coated element or feature to moisture. As an example, a moisture-resistant coating may resist wetting or penetration by one or more types of moisture, or it may be impermeable to one or more types of moisture or substantially impermeable to one or more types of moisture. The term “substantially impermeable” indicates that over long durations of time, some moisture may migrate through the coating. Long durations of time may refer to periods of 5 years, 10 years, 15 years, or 20 years. When subjected to temperatures below 100° C., a long duration of time may refer to 20 years. “Moisture-resistant” may be defined, in some cases, as having a water vapor transmission less than 0.25 g-mil/100 in²-day (at 38° C. and 90% relative humidity). Both moisture-impermeable and substantially moisture-impermeable barriers are, for the sake of simplicity, referred to herein as “moisture impermeable” barriers.

In some embodiments, a moisture-resistant coating may be impermeable to, substantially impermeable to, and/or repel water, an aqueous solution (e.g., salt solutions, acidic solutions, basic solutions, drinks, etc.) or vapors of water or other aqueous materials (e.g., humidity, fogs, mists, wetness, etc.). The terms “moisture-resistant” and “moisture-resistance” may also refer to the ability of a coating to restrict permeation of or repel organic liquids or vapors (e.g., organic solvents, other organic materials in liquid or vapor form, etc.), as well as a variety of other substances, corrosive materials, or conditions that might damage a substrate (e.g., a moisture-sensitive substrate, etc.), such as an electronic device or its components.

In some embodiments, the parylene coating includes one of parylene C (poly(chloro-p-xylylene)) which may have a superior moisture barrier than other known parylenes, parylene F (sometimes known as parylene AF-4 (poly(α,α,α′,α′-tetrafluoro-p-xylylene)) or parylene VT-4 (poly(tetrafluoro-p-xylylene))), parylene N, or parylene D. In certain implementations, reference to parylene F can specifically refer to parylene-VT4, parylene-AF4, or any other parylene with a fluorine atom or atoms in the molecular structure. Other types of protective coatings are contemplated herein.

Embodiments of moisture-resistant protection, as described herein, may be particularly useful for protecting state of the art mobile electronic devices from accidental or incidental exposure to moisture. Other aspects, as well as features and advantages of various aspects, of the disclosed subject matter will be apparent to those of ordinary skill in the art through consideration of this disclosure and the appended claims.

In some embodiments, post-treatment processes are performed on the substrate and deposited protective coating. The post-treatment processes may, in some embodiments, be performed at least in part by the plasma generation system 202. Similar to what is described in conjunction with the pre-treatment processes, the plasma generation system 202 may generate plasma for post-treatment processes. The post-treatment processes are also performed within the multipurpose deposition chamber 100.

In some embodiments, the multipurpose deposition chamber 100 remains under vacuum during the deposition process and the post-treatment process. That is, the vacuum is not broken between the deposition process and any post-treatment process. It is also contemplated that the post-treatment processes may be performed on substrates that previously were subjected to pre-treatment processes and deposition processes.

In some embodiments, the post-treatment processes are surface treatments of the protective coating. In some embodiments, the surface treatments may roughen the surface of the protective coating. In some embodiments, the surface treatments may fluorinate the surface of the protective coating.

In some embodiments, the post-treatment processes increase hydrophobic properties of the surface of the protective coating. In other embodiments, the post-treatment processes increase hydrophilic properties of the surface of the protective coating.

In some embodiments, the post-treatment processes may include an O₂/SF₆ post-treatment. The O₂/SF₆ post-treatment may increase the hydrophobic properties of the protective coating. In some embodiments, the post-treatment processes may include a C₄F₈, C₃F₆, CF₄, or other fluorocarbon gases or other fluorinated gases. In some embodiments, the post-treatment processes may include post-treatment with combinations of fluorocarbon gases, fluorinated gases, and/or the other gases described above. Other types of post-treatment processes are contemplated herein.

In some embodiments, the multipurpose deposition chamber 100 is further configured for cleaning. In some embodiments, the cleaning of the multipurpose deposition chamber 100 is done by plasma etching. In some embodiments, the plasma etching is done by oxygen. In some embodiments, the cleaning of the multipurpose deposition chamber 100 is by reactive ion etching. Various gases are contemplated for cleaning including, but not limited to, NF₃, CF₄, C₂F₆, C₃F₈, He, NF₃/C₃F₈/O₂ gas mixture, or C₃F₈/Ar/O₂ gas mixture and other similar gases and gas mixtures or plasmas of the preceding. Utilizing plasma may reduce or eliminate manual cleaning and may reduce labor expense, system downtime, human error, and may extend system life.

Described herein is a combined multipurpose deposition chamber 100 that incorporates deposition of a protective coating, such as parylene in some embodiments, with one or more of pre-treatment processes in the multipurpose deposition chamber 100, post-treatment processes in the multipurpose deposition chamber 100, or an automated cleaning of the multipurpose deposition chamber 100. In some embodiments, the multipurpose deposition chamber 100 is configured to incorporate pre-treatment processes in the multipurpose deposition chamber 100, deposition of a protective coating in the multipurpose deposition chamber 100, and post-treatment processes in the multipurpose deposition chamber 100. In some embodiments, the multipurpose deposition chamber 100 is configured to incorporate pre-treatment processes in the multipurpose deposition chamber 100, deposition of a protective coating in the multipurpose deposition chamber 100, and post-treatment processes in the multipurpose deposition chamber 100, and automated cleaning of the multipurpose deposition chamber 100.

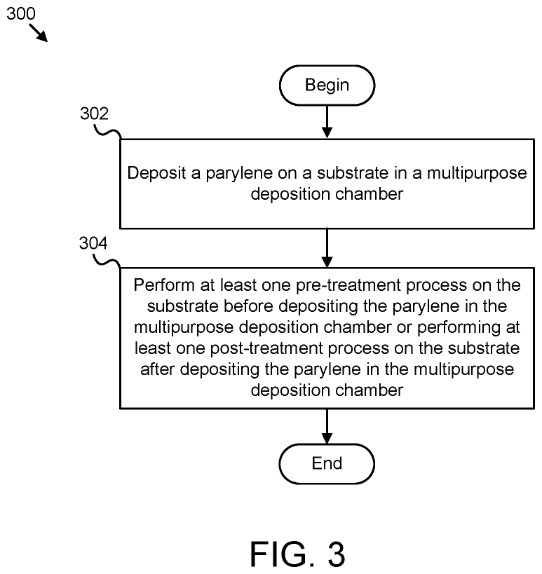

Referring to FIG. 3, a method 300 is disclosed. At block 302, the method 300 includes depositing a parylene on a substrate in a multipurpose deposition chamber. At block 304, the method 300 includes performing at least one pre-treatment process on the substrate before depositing the parylene in the multipurpose deposition chamber or performing at least one post-treatment process on the substrate after depositing the parylene in the multipurpose deposition chamber. The method 300 then ends.

In some embodiments, the method further includes performing the at least one pre-treatment process on the substrate before depositing the parylene in the multipurpose deposition chamber and performing the at least one post-treatment process on the substrate after depositing the parylene in the multipurpose deposition chamber.

In some embodiments, the at least one pre-treatment process is a radio-frequency plasma pre-treatment of the substrate. In some embodiments, the at least one pre-treatment process is an O₂/Ar plasma pre-treatment of the substrate. In some embodiments, the pre-treatment process may include other types of gases including, but not limited to, O₂, Ar, He, SF₆, C₄F₈, C₃F₆, CF₄, or other fluorinated gases, or other halogenated gases, or combinations thereof that increase the hydrophilicity or the hydrophobicity of the substrate. In some embodiments, the at least one post-treatment process is an O₂/SF₆ plasma post-treatment of the substrate. In some embodiments, the method further includes performing a cleaning of the multipurpose deposition chamber, wherein the cleaning is a reactive ion etching or a plasma etching. In some embodiments, the plasma etching may be reactive ion etching, planar etching, inductively coupled plasma etching, capacitively coupled plasma etching, or deep reactive ion etching.

In some embodiments, the post-treatment processes may include an O₂/SF₆ post-treatment. The O₂/SF₆ post-treatment may increase the hydrophobic properties of the protective coating. In some embodiments, the post-treatment process may include up to ten minutes of oxygen treatment. In some embodiments, the post-treatment process may include between six minutes and seven minutes of oxygen treatment or other varying times of oxygen treatment. In some embodiments, the oxygen is an oxygen plasma. In some embodiments, the oxygen plasma is configured to rough the surface and reactivate the inert parylene surface to enable subsequent chemical reaction with fluorine ions.

In some embodiments, the post-treatment process may include one minute of SF₆ treatment at 10 mTorr. In some embodiments, the SF₆ treatment occurs directly after the oxygen treatment. In some embodiments, the SF₆ treatment is separate from the oxygen treatment. In some embodiments, the SF₆ treatment is performed without the oxygen treatment. In some embodiments, the post-treatment processes may include post-treatment of fluorocarbon gases including, but not limited to, O₂, Ar, He, SF₆, C₄F₈, C₃F₆, CF₄, or other fluorinated gases, or other fluorocarbon gases, or other halogenated gases, or combinations thereof. Other types of post-treatment processes are contemplated herein.

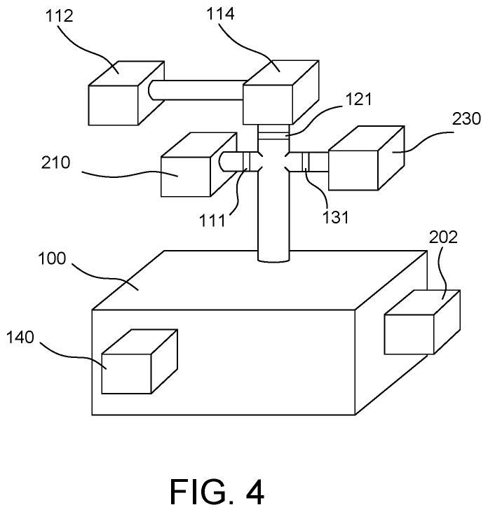

Referring to FIG. 4, a multipurpose deposition chamber 100 is coupled to a vaporizer 112 and a pyrolizer 114 which process the parylene prior to entering the multipurpose deposition chamber 100. In some embodiments, the system includes a vacuum 140 for maintaining a pressure (e.g., a negative pressure, or vacuum, etc.) within the multipurpose deposition chamber 100. The multipurpose deposition chamber 100 may communicate with a vacuum pump and other elements that may facilitate the deposition of parylene material onto the substrate. One or more valves, including valve 121, may also control the flow of the parylene materials through the system and onto the substrate. The illustrated embodiment includes a conduit between the pyrolizer 114 and the multipurpose deposition chamber 100. The illustrated embodiment also includes a conduit between the pyrolizer 114 and the vaporizer 112. In some embodiments, the conduit includes a valve 121 to regulate the flow of material from the pyrolizer 114 to the multipurpose deposition chamber 100.

The vaporizer 112 may vaporize one or more types of parylene precursors for the formation of parylene materials such as parylene C (poly(chloro-p-xylylene)), parylene F (which can specifically refer to parylene-VT4, parylene-AF4, or any other parylene with a fluorine atom or atoms in the molecular structure), parylene N (poly(p-xylylene)), parylene D (poly(dichloro-p-xylylene)), parylene A (amino-modified parylene), etc.

In some embodiments, the multipurpose deposition chamber 100 may also be coupled to a pre-treatment source 210. The pre-treatment source 210 may be configured to produce, generate, or provide gases or other components or products used for the pre-treatment processes described herein. In some embodiments, the components or products may be provided directly into the multipurpose deposition chamber 100 through the same conduit as the parylene. The pre-treatment source 210 may be isolated by a valve 111. In some embodiments, the components or products may be further processed within the multipurpose deposition chamber 100 by a plasma generation system 202. In some embodiments, the plasma generation system 202 is coupled to the multipurpose deposition chamber 100 as depicted in FIG. 4 or may be coupled directly to the pre-treatment source 210.

In some embodiments, the multipurpose deposition chamber 100 may also be coupled to a post-treatment source 230. The post-treatment source 230 may be configured to produce, generate, or provide gases or other components used for the post-treatment processes described herein. In some embodiments, the components or products may be provided directly into the multipurpose deposition chamber 100 through the same conduit as the parylene. The post-treatment source 230 may be isolated by a valve 131. In some embodiments, the components or products may be further processed within the multipurpose deposition chamber 100 by a plasma generation system 202. In some embodiments, the plasma generation system 202 is coupled to the multipurpose deposition chamber 100 as depicted in FIG. 4 or may be coupled directly to the post-treatment source 230.

In some embodiments, the multipurpose deposition chamber 100 may be coupled to both the pre-treatment source 210 and the post-treatment source 230. In some embodiments, the multipurpose deposition chamber 100 may be coupled to only the pre-treatment source 210. In other embodiments, the multipurpose deposition chamber 100 may be coupled to only the post-treatment source 230.

In some embodiments, the multipurpose deposition chamber 100 is coupled to or includes a plasma generation system 202. The plasma generation system 202, in FIG. 4, is an in situ plasma generation system. In other embodiments, the plasma generation system 202 remotely generates plasma which is then provided to the multipurpose deposition chamber 100 or the pre-treatment source 210 or the post-treatment source 230. In some embodiments, the plasma may be generated by radio frequency. In other embodiments, the plasma may be generated by microwaves. In some embodiments, the plasma is generated by direct current. In some embodiments, the plasma is generated by hot filament. Other forms of energy are contemplated to generate the plasma.

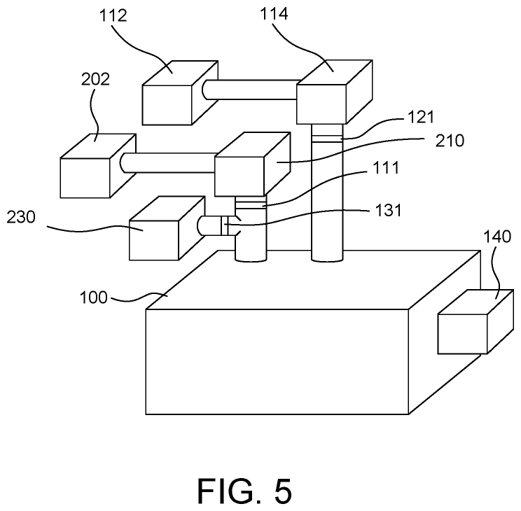

Referring to FIG. 5, a multipurpose deposition chamber 100. Many of the features and configurations of the multipurpose deposition chamber 100 may be the same as is described in conjunction with FIGS. 1, 2, and 4. While not repeated for the sake of brevity, some or all of the features and configurations of FIGS. 1, 2, and 4 may be combined with the features shown and described with FIG. 5. Description in conjunction with each of these Figures is not meant to be limited to the Figure in which the description is found and may be applied to each of the other descriptions and is not repeated only for the sake of brevity.

In FIG. 5, the pre-treatment source 210 and the post-treatment source 230 are coupled together and separate from the vaporizer 112 and pyrolizer 114. In some embodiments, the pre-treatment source 210 and the post-treatment source 230 will be the same. As depicted in FIG. 5, the plasma generation system 202 is coupled to the pre-treatment source 210. In other embodiments, the plasma generation system 202 may be coupled to post-treatment source 230. In some embodiments, the plasma generation system 202 is coupled to both the pre-treatment source 210 and the post-treatment source 230.

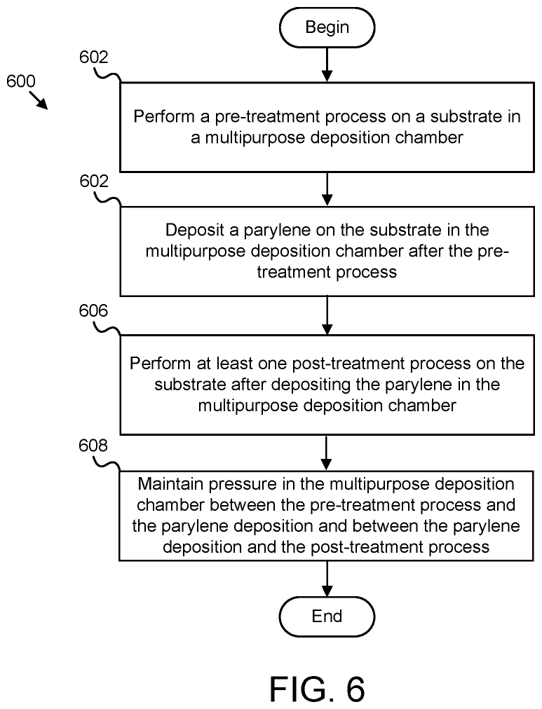

Referring to FIG. 6, a method 600 is disclosed. At block 602, the method 600 includes performing at least one pre-treatment process on a substrate in a multipurpose deposition chamber. At block 604, the method 600 includes depositing a parylene on the substrate in the multipurpose deposition chamber after the pre-treatment process. At block 606, the method 600 includes performing at least one post-treatment process on the substrate in the multipurpose deposition chamber after depositing the parylene. At block 608, the method 600 includes maintaining pressure in the multipurpose deposition chamber between the pre-treatment process and the parylene deposition and between the parylene deposition and the post-treatment process. The method 600 then ends.

In some embodiments, the at least one pre-treatment process is a radio-frequency plasma pre-treatment of the substrate. In some embodiments, the at least one pre-treatment process is an O₂/Ar plasma pre-treatment of the substrate. In some embodiments, the at least one post-treatment process is an O₂/SF₆ plasma post-treatment of the substrate. In some embodiments, the method further includes performing a cleaning of the multipurpose deposition chamber, wherein the cleaning is a reactive ion etching.

Although the foregoing disclosure provides many specifics, these should not be construed as limiting the scope of any of the ensuing claims. Other embodiments may be devised which do not depart from the scopes of the claims. Features from different embodiments may be employed in combination. The scope of each claim is, therefore, indicated and limited only by its plain language and the full scope of available legal equivalents to its elements.

Reference throughout this specification to features, advantages, or similar language does not imply that all of the features and advantages that may be realized with the subject matter of the present disclosure should be or are in any single embodiment. Rather, language referring to the features and advantages is understood to mean that a specific feature, advantage, or characteristic described in connection with an embodiment is included in at least one embodiment of the present disclosure. Thus, discussion of the features and advantages, and similar language, throughout this specification may, but do not necessarily, refer to the same embodiment.

In the above description, certain terms may be used such as “up,” “down,” “upper,” “lower,” “horizontal,” “vertical,” “left,” “right,” and the like. These terms are used, where applicable, to provide some clarity of description when dealing with relative relationships. But, these terms are not intended to imply absolute relationships, positions, and/or orientations. For example, with respect to an object, an “upper” surface can become a “lower” surface simply by turning the object over. Nevertheless, it is still the same object. Further, the terms “including,” “comprising,” “having,” and variations thereof mean “including but not limited to” unless expressly specified otherwise. An enumerated listing of items does not imply that any or all of the items are mutually exclusive and/or mutually inclusive, unless expressly specified otherwise. The terms “a,” “an,” and “the” also refer to “one or more” unless expressly specified otherwise.

Additionally, instances in this specification where one element is “coupled” to another element can include direct and indirect coupling. Direct coupling can be defined as one element coupled to and in some contact with another element. Indirect coupling can be defined as coupling between two elements not in direct contact with each other, but having one or more additional elements between the coupled elements. Further, as used herein, securing one element to another element can include direct securing and indirect securing. Additionally, as used herein, “adjacent” does not necessarily denote contact. For example, one element can be adjacent another element without being in contact with that element.

As used herein, the phrase “at least one of”, when used with a list of items, means different combinations of one or more of the listed items may be used and only one of the items in the list may be needed. The item may be a particular object, thing, or category. In other words, “at least one of” means any combination of items or number of items may be used from the list, but not all of the items in the list may be required. For example, “at least one of item A, item B, and item C” may mean item A; item A and item B; item B; item A, item B, and item C; or item B and item C. In some cases, “at least one of item A, item B, and item C” may mean, for example, without limitation, two of item A, one of item B, and ten of item C; four of item B and seven of item C; or some other suitable combination.

As used herein, a system, apparatus, structure, article, element, component, or hardware “configured to” perform a specified function is indeed capable of performing the specified function without any alteration, rather than merely having potential to perform the specified function after further modification. In other words, the system, apparatus, structure, article, element, component, or hardware “configured to” perform a specified function is specifically selected, created, implemented, utilized, programmed, and/or designed for the purpose of performing the specified function. As used herein, “configured to” denotes existing characteristics of a system, apparatus, structure, article, element, component, or hardware which enable the system, apparatus, structure, article, element, component, or hardware to perform the specified function without further modification. For purposes of this disclosure, a system, apparatus, structure, article, element, component, or hardware described as being “configured to” perform a particular function may additionally or alternatively be described as being “adapted to” and/or as being “operative to” perform that function.

Although the operations of the method(s) herein are shown and described in a particular order, the order of the operations of each method may be altered so that certain operations may be performed in an inverse order or so that certain operations may be performed, at least in part, concurrently with other operations. In another embodiment, instructions or sub-operations of distinct operations may be implemented in an intermittent and/or alternating manner.

The present subject matter may be embodied in other specific forms without departing from its spirit or essential characteristics. The described embodiments are to be considered in all respects only as illustrative and not restrictive.

In the above description, specific details of various embodiments are provided. However, some embodiments may be practiced with less than all of these specific details. In other instances, certain methods, procedures, components, structures, and/or functions are described in no more detail than to enable the various embodiments of the invention, for the sake of brevity and clarity.

What is claimed:

1. A method for depositing parylene onto a substrate, comprising:
depositing a parylene on a substrate in a multipurpose deposition chamber;
performing at least one pre-treatment process on the substrate before depositing the parylene in the multipurpose deposition chamber or performing at least one post-treatment process on the substrate after depositing the parylene in the multipurpose deposition chamber, and
maintaining pressure in the multipurpose deposition chamber between the depositing the parylene and the performing the at least one pre-treatment process or the performing the at least one post-treatment process.

2. The method of claim 1, further comprising performing the at least one pre-treatment process on the substrate before depositing the parylene in the multipurpose deposition chamber and performing the at least one post-treatment process on the substrate after depositing the parylene in the multipurpose deposition chamber.

3. The method of claim 2, wherein the at least one pre-treatment process is a radio-frequency, direct current, microwave, or hot filament plasma pre-treatment of the substrate.

4. The method of claim 2, wherein the at least one pre-treatment process is an O₂ or an O₂/Ar plasma pre-treatment of the substrate.

5. The method of claim 2, wherein the at least one post-treatment process is an O₂/SF₆ plasma post-treatment of the substrate.

6. The method of claim 2, further comprising performing a cleaning of the multipurpose deposition chamber, wherein the cleaning is done by etching.

7. The method of claim 2, further comprising maintaining pressure in the multipurpose deposition chamber between the performing the at least one pre-treatment process and the depositing the parylene, and
maintaining pressure in the multipurpose deposition chamber between the depositing the parylene and the performing the at least one post-treatment process.

8. The method of claim 2, further comprising applying a plasma etching to the multipurpose deposition chamber after performing the post-treatment.

9. The method of claim 2, wherein the post-treatment process includes an oxygen treatment.

10. The method of claim 2, wherein the post-treatment process includes a fluorinated gas treatment.

11. A deposition system, comprising:
a multipurpose deposition chamber configured to deposit parylene on a plurality of electronic devices, wherein the multipurpose deposition chamber is configured to also process pre-treatment of the plurality of electronic devices prior to deposition of the parylene or process post-treatment of the plurality of electronic devices after deposition of the parylene.

12. The deposition system of claim 11, further comprising a capacitively coupled radio frequency plasma generation system coupled to the multipurpose deposition chamber.

13. The deposition system of claim 11, further comprising a remote radio frequency plasma generation system coupled to the multipurpose deposition chamber.

14. The deposition system of claim 11, further comprising a microwave plasma generation system.

15. The deposition system of claim 11, wherein the at least one post-treatment process is a halogenated gas post-treatment of the substrate.

16. The deposition system of claim 11, further comprising a pre-treatment source coupled to the multipurpose deposition chamber.

17. The deposition system of claim 11, further comprising a post-treatment source coupled to the multipurpose deposition chamber.

18. The deposition system of claim 11, wherein the at least one pre-treatment process is an O₂/Ar plasma pre-treatment of the substrate.

19. A deposition system, comprising:
a multipurpose deposition chamber, wherein the multipurpose deposition chamber is configured to deposit parylene on a plurality of electronic devices, wherein the multipurpose deposition chamber is configured to also process pre-treatment of the plurality of electronic devices prior to deposition of the parylene, and wherein the multipurpose deposition chamber is configured to also process post-treatment of the plurality of electronic devices after deposition of the parylene;
a pre-treatment source coupled to the multipurpose deposition chamber; and
a post-treatment source coupled to the multipurpose deposition chamber.

20. The deposition system of claim 19, further comprising a capacitively coupled radio frequency plasma generation system coupled to the multipurpose deposition chamber.
